(19) United States
(12) Patent Application Publication
(10) Pub. No.: US 2018/0138058 A1
(43) Pub. Date: May 17, 2018

(54) SUBSTRATE PROCESSING APPARATUS, SUBSTRATE PROCESSING METHOD, AND STORAGE MEDIUM

(71) Applicant: Tokyo Electron Limited, Tokyo (JP)

(72) Inventors: Keisuke Egashira, Kumamoto (JP); Yosuke Kawabuchi, Kumamoto (JP); Gentaro Goshi, Kumamoto (JP); Hiroki Ohno, Kumamoto (JP); Hiroshi Marumoto, Kumamoto (JP); Takuro Masuzumi, Kumamoto (JP); Kento Tsukano, Kumamoto (JP); Shotaro Kitayama, Kumamoto (JP); Satoshi Okamura, Kumamoto (JP)

(21) Appl. No.: 15/805,291

(22) Filed: Nov. 7, 2017

(30) Foreign Application Priority Data
Nov. 14, 2016 (JP) 2016-221740

(51) Int. Cl. H01L 21/67; B08B 3/08

(52) U.S. Cl. CPC H01L 21/67034; H01L 21/67051; H01L 21/67248; H01L 21/67173; B08B 3/08

(57) ABSTRACT

A substrate processing apparatus of the present disclosure includes: a processing container; and a supply line which connects the processing container with a fluid source that delivers a supercritical processing fluid. A first opening/closing valve is provided in the supply line. A first throttle is provided on a downstream side of the first opening/closing valve to change the supercritical processing fluid flowing through the supply line to a gaseous state when a pressure within the processing container is equal to or lower than a critical pressure of the processing fluid. A first filter is provided on a downstream side of the first throttle.

### CROSS-REFERENCE TO RELATED APPLICATIONS

This application is based on and claims priority from Japanese Patent Application No. 2016-221740 filed on Nov. 14, 2016 with the Japan Patent Office, the disclosure of which is incorporated herein in its entirety by reference.

### TECHNICAL FIELD

The present disclosure relates to a technology of removing a liquid remaining on a surface of a substrate using a supercritical processing fluid.

### BACKGROUND

In a semiconductor device manufacturing process of forming a laminated structure of an integrated circuit on a surface of, for example, a semiconductor wafer (hereinafter, referred to as a “wafer”) which is a substrate, a liquid processing such as chemical liquid cleaning or wet etching is performed. Recently, a drying method using a supercritical processing fluid has been used as a drying method of a substrate after the liquid processing (see, e.g., Japanese Patent Laid-Open Publication No. 2013-012538).

The supercritical processing fluid is delivered from a processing fluid source and the processing fluid is supplied to a processing container via a supply line. A filter is provided in the supply line to remove particles included in the processing fluid. However, when a processing is actually carried out, the particles included in the supercritical processing fluid may not be sufficiently removed by the filer. Thus, an event where the particles attached to the surface of the processed substrate may not be sufficiently reduced is likely to occur.

### SUMMARY

The present disclosure relates to a substrate processing apparatus for processing a substrate using a supercritical processing fluid, the substrate processing apparatus including: a processing container in which the substrate is accommodated; a supply line configured to connect the processing container with a fluid source that delivers the supercritical processing fluid; a first opening/closing valve provided in the supply line; a first throttle provided on a downstream side of the first opening/closing valve of the supply line and configured to change the supercritical processing fluid flowing through the supply line to a gaseous state when a pressure within the processing container is equal to or lower than a critical pressure of the processing fluid; and a first filter provided on a downstream side of the first throttle of the supply line.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating an overall configuration of a substrate processing system.

FIG. 2 is an external perspective view of a processing container of a supercritical processing apparatus.

FIG. 3 is a cross-sectional view of a processing container.

FIG. 4 is a piping system diagram of the supercritical processing apparatus.

FIGS. 5A to 5D are views for explaining a drying mechanism of IPA.

FIG. 6 is a graph illustrating a variation of a pressure in the processing container during a drying processing.

FIG. 7 is a graph illustrating a relationship among a CO₂ concentration, a critical temperature, and a critical pressure in a mixed fluid of IPA and CO₂.

FIG. 8 is a schematic view for explaining another exemplary embodiment of the piping system, which is a simplified view of the piping system diagram of FIG. 4.

FIG. 9 is a schematic view for explaining a third exemplary embodiment of the piping system.

FIG. 10 is a schematic view for explaining a fourth exemplary embodiment of the piping system.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

The present disclosure provides a technology of capable of sufficiently exerting a filtration performance of a filter provided in a supply line that supplies a processing fluid from a processing fluid source to a processing container and sufficiently reducing a particle level of a substrate after the processing.

According to one exemplary embodiment of the present disclosure, provided is a substrate processing apparatus for processing a substrate using a supercritical processing fluid. The substrate processing apparatus includes: a processing container in which the substrate is accommodated; a supply line configured to connect the processing container with a fluid source that delivers the supercritical processing fluid; a first opening/closing valve provided in the supply line; a first throttle provided on a downstream side of the first opening/closing valve of the supply line and configured to change the supercritical processing fluid flowing through the supply line to a gaseous state when a pressure within the processing container is equal to or lower than a critical pressure of the processing fluid; and a first filter provided on a downstream side of the first throttle of the supply line.

According to another exemplary embodiment of the present disclosure, provided is a substrate processing apparatus for processing a substrate using a supercritical processing fluid. The substrate processing apparatus includes: a processing container in which the substrate is accommodated; a supply line configured to connect the processing container with a fluid source that delivers the supercritical processing fluid; a first throttle provided on a downstream side of the first opening/closing valve of the supply line; a first filter provided on a downstream side of the first throttle of the supply line; a first branch line that branches off from the supply line at a position between the first opening/closing valve and the first throttle, and joins the supply line at a position between the first throttle and the first filter; and a second throttle provided in the first branch line.

According to a third exemplary embodiment of the present disclosure, provided is a substrate processing apparatus for processing a substrate using a supercritical processing fluid. The substrate processing apparatus includes: a processing container in which the substrate is accommodated; a supply line configured to connect the processing container with a fluid source that delivers the supercritical processing fluid; a first opening/closing valve provided in the supply line; a first throttle provided on a downstream side of the first opening/closing valve of the supply line; a first filter provided on a downstream side of the first throttle of the supply line; a first branch line that branches off from the supply line at a position between the first opening/closing valve and the first throttle, and joins the supply line at a position between the first filter and the processing container; and a second throttle and a second filter provided in the first branch line.

According to a fourth exemplary embodiment of the present disclosure, provided is a substrate processing method. The substrate processing method includes: carrying the substrate into a processing container in which the substrate is accommodated; and filling an inside of the processing container accommodating the substrate with a supercritical processing fluid by supplying the processing container with a processing fluid from a fluid source, wherein, in the filling, when a pressure within the processing container is equal to or lower than a critical pressure of the processing fluid, the supercritical processing fluid supplied from the fluid source is changed to a gaseous state and supplied to the processing container through a first filter.

According to a fifth exemplary embodiment of the present disclosure, provided is a non-transitory computer-readable storage medium storing a computer executable program that, when executed, causes a computer to control an operation of a substrate processing apparatus and execute the above-described substrate processing method.

According to the exemplary embodiment of the present disclosure, until a certain period of time elapses from a point of time when the first opening/closing valve is opened (i.e., before the pressure on the downstream side of the throttle becomes sufficiently higher), the processing fluid flowing out of the throttle comes into a gaseous state, not into a supercritical state due to the pressure loss by the throttle, so that the filtration performance of the filter may be enhanced.

Hereinafter, exemplary embodiments of the present disclosure will be described with reference to the accompanying drawings. The configurations illustrated in the figures attached to the present specification may include portions in which sizes, scales, and the like are changed from actual objects for convenience of illustration and understanding.

[Configuration of Substrate Processing System]

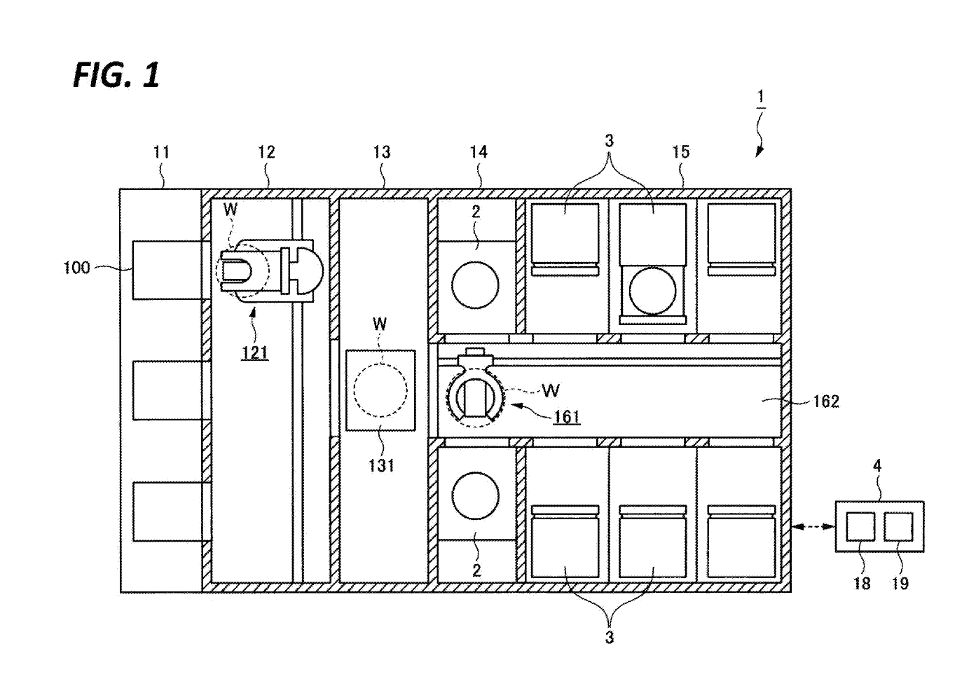

As illustrated in FIG. 1, a substrate processing system 1 includes: a plurality of cleaning apparatuses 2 (two cleaning apparatuses 2 in the example illustrated in FIG. 1) that performs a cleaning processing by supplying a cleaning liquid to a wafer W; and a plurality of supercritical processing apparatuses 3 (six supercritical processing apparatuses 3 in the example illustrated in FIG. 1) that remove a drying prevention liquid (in this exemplary embodiment, isopropyl alcohol (IPA)) remaining on the wafers W after the cleaning processing by bringing the liquid into contact with a supercritical processing liquid (in this exemplary embodiment, carbon dioxide (CO₂)).

In this substrate processing system 1, front opening unified pods (FOUPs) 100 are placed on a placing section 11, and the wafers W stored in the FOUPs 100 are delivered to a cleaning processing section 14 and a supercritical processing section 15 via a carry-in/out section 12 and a delivery section 13. In the cleaning processing section 14 and the supercritical processing section 15, the wafers W are first carried into the cleaning apparatuses 2 provided in the cleaning processing section 14 and subjected to a cleaning processing. Thereafter, the wafers W are carried into the supercritical processing apparatuses 3 provided in the supercritical processing section 15 and subjected to a drying processing of removing the IPA from the wafers W. In FIG. 1, reference numeral “121” denotes a first conveyance mechanism that conveys the wafers W between the FOUPs 100 and the delivery section 13, and reference numeral “131” denotes a delivery shelf that plays a role as a buffer on which the wafers W conveyed between the carry-in/out section 12 and the cleaning processing section 14 and the supercritical processing section 15 are temporarily placed.

A wafer conveyance path 162 is connected to an opening of the delivery section 13, and the cleaning processing section 14 and the supercritical processing section 15 are provided along the wafer conveyance path 162. One cleaning apparatus 2 is disposed in the cleaning processing section 14 with the wafer conveyance path 162 interposed therebetween, and a total of two cleaning apparatuses are provided. The supercritical processing section 15 is provided with three supercritical processing apparatuses 3 functioning as substrate processing apparatuses that perform a drying processing of removing IPA from the wafer W with the wafer conveyance path 162 interposed therebetween, and a total of six supercritical processing apparatuses 3 are provided. A second conveyance mechanism 161 is provided in the wafer conveyance path 162, and the second conveyance mechanism 161 is provided so as to be movable in the wafer conveyance path 162. The wafers W disposed on the delivery shelf 131 are received by the second conveyance mechanism 161, and the second conveyance mechanism 161 carries the wafers W into the cleaning apparatuses 2 and the supercritical processing apparatuses 3. In the meantime, the number and arrangement of the cleaning apparatuses 2 and the supercritical processing apparatuses 3 are not particularly limited, and appropriate numbers of the cleaning apparatuses 2 and the supercritical processing apparatuses 3 are arranged in an appropriate manner depending on the number of the wafer W per unit time and the processing time of each cleaning apparatus 2 and each supercritical processing apparatus 3.

Each cleaning apparatus 2 is configured as a single-wafer apparatus that cleans the wafers W one by one, for example, by spin cleaning. In this case, the cleaning processing of the wafer W may be performed by supplying a cleaning liquid or a rinsing liquid for washing the cleaning liquid to a surface of the wafer W to be processed at an appropriate timing, while holding horizontally and rotating the wafer W around the vertical axis. The chemical liquid and the rinse liquid used in the cleaning apparatus 2 are not particularly limited. For example, an SC1 liquid (i.e., a mixture of ammonia and hydrogen peroxide), which is an alkaline chemical liquid, may be supplied to the wafer W to remove particles and organic contaminants from the wafer W. Thereafter, deionized water (DIW), which is a rinse liquid, is supplied to the wafer W, and the SC1 liquid may be washed away from the wafer W. In addition, a diluted hydrofluoric acid (DHF) aqueous solution, which is an acidic chemical liquid, may be supplied to the wafer W to remove a natural oxide film, and then DIW may be supplied to the wafer W to wash away the diluted hydrofluoric acid aqueous solution from the wafer W.

After the rinse processing by the DIW is completed, the cleaning apparatus 2 supplies the IPA to the wafer W as a drying prevention liquid while rotating the wafer W, and replaces the DIW remaining on the processed surface of the wafer W with the IPA. Thereafter, the rotation of the wafer W is stopped gently. At this time, a sufficient amount of the IPA is supplied to the wafer W, and the surface of the wafer W on which a semiconductor pattern is formed is in a state of being filled with the IPA, and a liquid film of the IPA is formed on the surface of the wafer W. The wafer W is carried out of the cleaning apparatus 2 by the second conveyance mechanism 161 while maintaining the state of being filled with the IPA.

The IPA applied to the surface of the wafer W in this manner serves to prevent drying of the wafer W. In particular, in order to suppress a so-called pattern collapse from occurring on the wafer W due to the evaporation of the IPA during the conveyance of the wafer W from the cleaning apparatus 2 to the supercritical processing apparatus 3, the cleaning apparatus 2 applies a sufficient amount of the IPA to the wafer W so that an IPA film having a relatively large thickness is formed on the surface of the wafer W.

The wafer W carried out of the cleaning apparatus 2 is carried into the processing container of the supercritical processing apparatus 3 by the second conveyance mechanism 161 in a state of being filled with the IPA, and is subjected to a drying processing of the IPA in the supercritical processing apparatus 3.

[Supercritical Processing Apparatus]

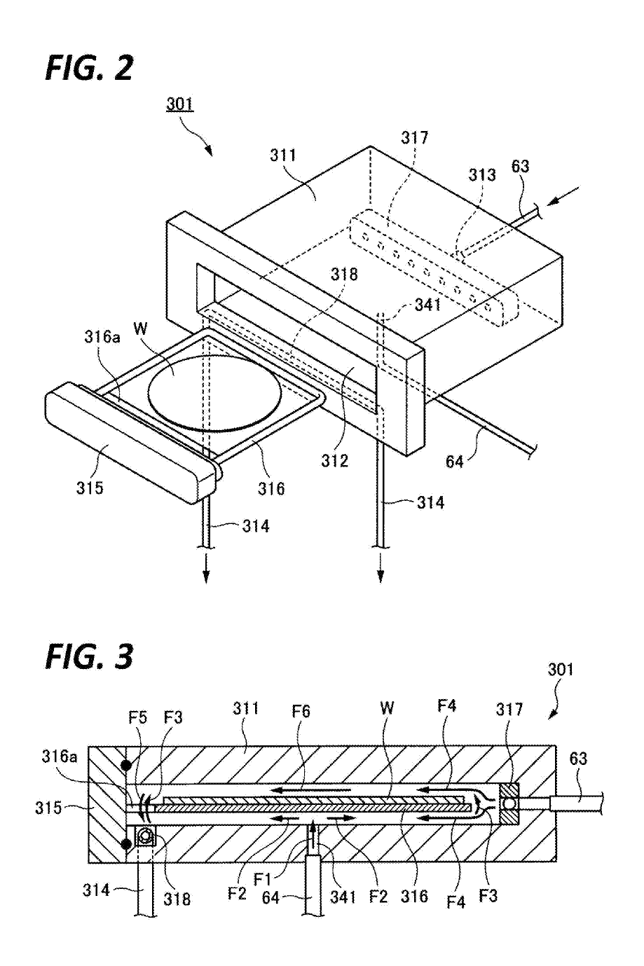

Hereinafter, the supercritical processing apparatus 3 will be described with reference to FIGS. 2 to 4.

As illustrated in FIGS. 2 and 3, a processing container 301 includes a container body 311 having an opening 312 for carry-in/out of a wafer W formed therein, a holding plate 316 that horizontally holds the wafer W, which is a processing target, and a cover member 315 configured to support the holding plate 316 and seal the opening 312 when the wafer W is carried into the container body 311.

The container body 311 is a container in which a processing space capable of accommodating the wafer W having a diameter of, for example, 300 mm is formed. A fluid supply header (first fluid supply unit) 317 is provided on one end side of the inside of the container body 311, and a fluid discharge header (fluid discharge unit) 318 is provided on the other end side thereof. In the illustrated example, the fluid supply header 317 is formed of a block having a plurality of openings (first fluid supply ports), and the fluid discharge header 318 is formed of a tube having a plurality of openings (fluid discharge ports). The first fluid supply ports of the fluid supply header 317 may be located at a slightly higher position than the upper surface of the wafer W held by the holding plate 316.

The configurations of the fluid supply header 317 and the fluid discharge header 318 are not limited to the illustrated example, and, for example, the fluid discharge header 318 may be formed of a block and the fluid supply header 317 may be formed of a tube.

When viewed from below, the holding plate 316 covers the entire lower surface of the wafer W. The holding plate 316 has an opening 316a at an end portion of the cover member 315 side. A processing fluid in the space above the holding plate 316 is guided to the fluid discharge header 318 through the opening 316a (see, e.g., arrow “F5” in FIG. 3).

The fluid supply header 317 supplies the processing fluid into the container body 311 (processing container 301) in a substantially horizontal direction. The horizontal direction referred to herein is a direction perpendicular to the vertical direction in which gravity acts, and is generally parallel to the direction in which the flat surface of the wafer W held by the holding plate 316 extends.

The fluid in the processing container 301 is discharged to the outside of the processing container 301 through the fluid discharge header 318. The fluid discharged through the fluid discharge header 318 includes not only the processing fluid supplied into the processing container 301 through the fluid supply header 317 but also the IPA remaining on the surface of the wafer W and dissolved in the processing fluid.

A fluid supply nozzle (second fluid supply unit) 341 configured to supply the processing fluid to the inside of the processing container 301 is provided at the bottom of the container body 311. In the illustrated example, the fluid supply nozzle 341 is constituted with an opening in a bottom wall of the container body 311. The fluid supply nozzle 341 is located immediately below the center of the wafer W and supplies the processing liquid into the processing container 301 in the vertical upward direction.

The processing container 301 further includes a pressing mechanism (not illustrated). The pressing mechanism serves to seal the processing space by pressing the cover member 315 toward the container body 311 against an internal pressure caused by a processing fluid in a supercritical state, which is supplied into the processing space. Further, thermal insulating materials, tape heaters (not illustrated), or the like may be provided on the ceiling wall and the bottom wall of the container body 311 so that the processing fluid supplied into the processing space maintains the temperature in a supercritical state.

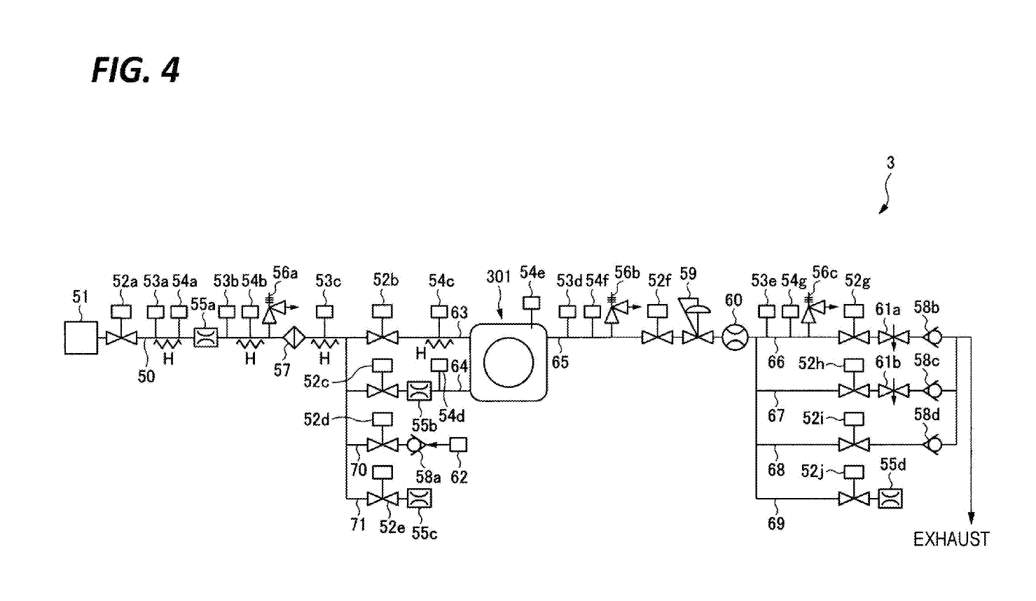

As illustrated in FIG. 4, the supercritical processing apparatus 3 has a fluid supply tank 51 which is a source of a high-pressure processing fluid in a supercritical state, for example, about 16 MPa to 20 MPa (megapascal). A main supply line 50 is connected to the fluid supply tank 51. The main supply line 50 branches off into a first supply line 63 connected to the fluid supply header (first fluid supply unit) 317 in the processing container 301 and a second supply line 64 connected to the fluid supply nozzle (second fluid supply unit) 341 on the way.

An opening/closing valve 52a, an orifice 55a (first throttle), a filter 57, and an opening/closing valve 52b are provided in this order from the upstream side between the fluid supply tank 51 and the fluid supply header 317 (i.e., the main supply line 50 and the first supply line 63 continuous thereto). The second supply line 64 branches off from the main supply line 50 at a position between the filter 57 and the opening/closing valve 52b. An opening/closing valve 52c is provided in the second supply line 64.

The orifice 55a is provided to reduce the flow rate of the processing fluid supplied from the fluid supply tank 51 in order to protect the wafer W. The filter 57 is provided to remove foreign matters (particle-causing substances) contained in the processing fluid flowing through the main supply line 50.

The supercritical processing apparatus 3 further includes a purge gas supply line 70 connected to a purging apparatus 62 via an opening/closing valve 52d and a check valve 58a, and a discharge line 71 connected to an external space of the supercritical processing apparatus 3 via an opening/closing valve 52e and an orifice 55c. The purge gas supply line 70 and the discharge line 71 are connected to a main supply line 50, a first supply line 63, and a second supply line 64.

The purge gas supply line 70 is used to fill the processing container 301 with an inert gas and maintain the processing container 301 in a clean state, for example, when the supplying of the processing fluid from the fluid supply tank 51 to the processing container 301 is stopped. The discharge line 71 is used to discharge the processing fluid remaining in the supply line between the opening/closing valve 52a and the opening/closing valve 52b to the outside, for example, when the supercritical processing apparatus 3 is turned off.

A main discharge line 65 is connected to the fluid discharge header 318 in the processing container 301. The main discharge line 65 branches off into a first discharge line 66, a second discharge line 67, a third discharge line 68, and a fourth discharge line 69 on the way.

An opening/closing valve 52f, a back pressure valve 59, a concentration sensor 60, and an opening/closing valve 52g are provided in this order from the upstream side in the main discharge line 65 and the first discharge line 66 continuous thereto.

The back pressure valve 59 is configured such that the back pressure valve 59 is opened when a primary side pressure (which is equal to the pressure in the processing container 301) exceeds a set pressure, and the primary side pressure is maintained at the set pressure by causing the fluid to flow to a secondary side. The set pressure of the back pressure valve 59 may be changed at any time by a controller 4.

The concentration sensor 60 is a sensor that measures the IPA concentration of the fluid flowing through the main discharge line 65.

On the downstream side of the opening/closing valve 52g, the first discharge line 66 is provided with a needle valve (variable throttle) 61a and a check valve 58b. The needle valve 61a is a valve that adjusts the flow rate of the fluid discharged to the outside of the supercritical processing apparatus 3 through the first discharge line 66.

The second discharge line 67, the third discharge line 68, and the fourth discharge line 69 branch off from the main discharge line 65 at a position between the concentration sensor 60 and the opening/closing valve 52g. An opening/closing valve 52h, a needle valve 61b, and a check valve 58c are provided in the second discharge line 67. An opening/closing valve 52i and a check valve 58d are provided in the third discharge line 68. An opening/closing valve 52j and an orifice 55d are provided in the fourth discharge line 69.

The second discharge line 67 and the third discharge line 68 are connected to a first discharge destination, for example, a fluid recovery apparatus, and the fourth discharge line 69 is connected to a second discharge destination, for example, an external air space of the supercritical processing apparatus 3 or a factory exhaust system.

When discharging the fluid from the processing container 301, one or more of the opening/closing valves 52g, 52h, 52i, and 52j are opened. In particular, when the supercritical processing apparatus 3 is stopped, the fluid present in the concentration sensor 60 and the first discharge line 66 between the concentration sensor 60 and the opening/closing valve 52g may be supplied to the outside of the supercritical processing apparatus 3 by opening the closing/opening valve 52j.

A pressure sensor configured to detect the pressure of the fluid and a temperature sensor configured to detect the temperature of the fluid are provided in various places on a line where the fluid of the supercritical processing apparatus 3 flows. In the example illustrated in FIG. 4, a pressure sensor 53a and a temperature sensor 54a are provided between the opening/closing valve 52a and the orifice 55a, a pressure sensor 53b and a temperature sensor 54b are provided between the orifice 55a and the filter 57, a pressure sensor 53c is provided between the filter 57 and the opening/closing valve 52b, a temperature sensor 54c is provided between the opening/closing valve 52b and the processing container 301, and a temperature sensor 54d is provided between the orifice 55b and the processing container 301. In addition, a pressure sensor 53d and a temperature sensor 54f are provided between the processing container 301 and the opening/closing valve 52f, and a pressure sensor 53e and a temperature sensor 54g are provided between the concentration sensor 60 and the opening/closing valve 52g. Further, a temperature sensor 54e configured to detect the temperature of the fluid in the processing container 301 is provided.

The main supply line 50 and the first supply line 63 are provided with four heaters H configured to regulate the temperature of the processing fluid supplied to the processing container 301. The heater H may be provided on the discharge line on the downstream side of the processing container 301.

A safety valve (relief valve) 56a is provided between the orifice 55a and the filter 57 of the main supply line 50, a safety valve 56b is provided between the processing container 301 and the opening/closing valve 52f, and a safety valve 56c is provided between the concentration sensor 60 and the opening/closing valve 52g. These safety valves 56a to 56c urgently discharge the fluid in the line to the outside when there is an abnormality such as when the pressure in the line (pipe) where these safety valves are provided becomes excessive.

The controller 4 receives measurement signals from various sensors (the pressure sensors 53a to 53e, the temperature sensors 54a to 54g, the concentration sensor 60, and the like) illustrated in FIG. 3 and transmits control signals (the opening/closing signals of the opening/closing valves 52a to 52j, the set pressure adjustment signals of the back pressure valve 59, the opening degree adjustment signals of the needle valves 61a and 61b, and the like) to various functional elements. The controller 4 is, for example, a computer, and includes an arithmetic unit 18 and a storage unit 19. The storage unit 19 stores a program that controls various processings performed in the substrate processing system 1. The arithmetic unit 18 controls the operation of the substrate processing system 1 by reading and executing the program stored in the storage unit 19. The program may be recorded in a computer-readable recording medium and installed from the recording medium to the storage unit 19 of the controller 4. The computer-readable recording medium may be, for example, a hard disc (HD), a flexible disc (HD), a compact disc (CD), a magnet optical disc (MO), or a memory card.

[Supercritical Drying Processing]

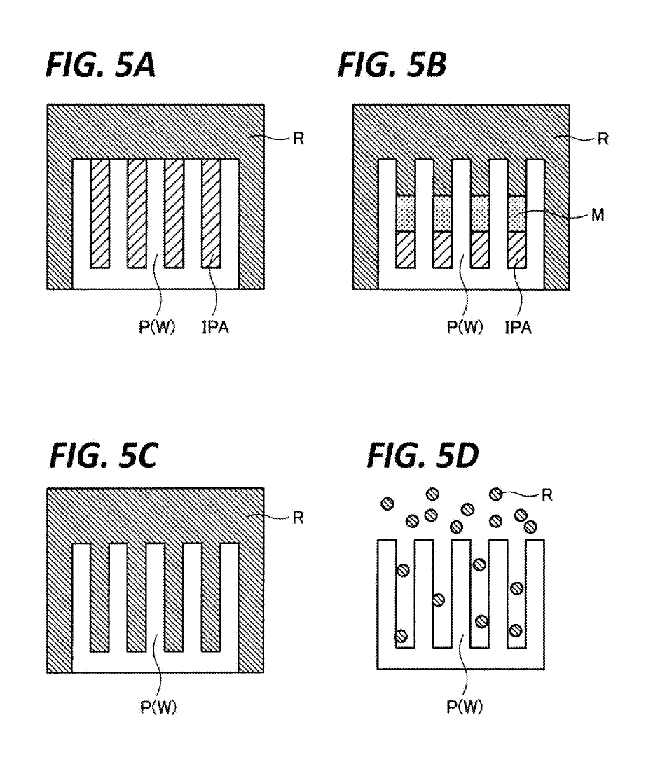

Next, a drying mechanism of the IPA using the processing fluid in a supercritical state (e.g., carbon dioxide (CO₂)) will be briefly described with reference to FIGS. 5A to 5D.

Immediately after the processing fluid R in a supercritical state is introduced into the processing container 301, there is IPA in the recess of a pattern P of the wafer W, as illustrated in FIG. 5A.

The IPA in the recess is gradually dissolved into the processing fluid R by contact with the processing fluid R in a supercritical state and is gradually replaced with the processing fluid R, as illustrated in FIG. 5B. At this time, in the recess, in addition to the IPA and the processing fluid R, there is a mixed fluid M in which the IPA and the processing fluid R are mixed.

As the replacement of the IPA with the processing fluid R progresses in the recess, the IPA existing in the recess decreases. Finally, as illustrated in FIG. 5C, only the processing fluid R in a supercritical state exists in the recess.

By lowering the pressure in the processing container 301 to an atmospheric pressure after the IPA is removed from the recess, as illustrated in FIG. 5D, the processing fluid R is changed from the supercritical state to the gaseous state and the inside of the recess is occupied only by the gas. In this way, the IPA in the recess of the pattern P is removed and the drying processing of the wafer W is completed.

Next, a drying method (substrate processing method) performed using the above-described supercritical processing apparatus 3 will be described. The drying method to be described below is automatically performed under control of the controller 4 based on a processing recipe and a control program stored in the storage unit 19.

<Carrying-In Step>

The wafer W which has been subjected to the cleaning processing is performed in the cleaning apparatus 2 is carried out of the cleaning apparatus 2 by the second conveyance mechanism 161 in a state where the recess of the pattern of the surface of the wafer W is filled with the IPA and a puddle of the IPA is formed on the surface thereof. The second conveyance mechanism 161 places the wafer on the holding plate 316. Thereafter, the holding plate 316 on which the wafer is placed enters the container body 311, and the cover member 315 is hermetically engaged with the container body 311. The carrying-in of the wafer is completed as described above.

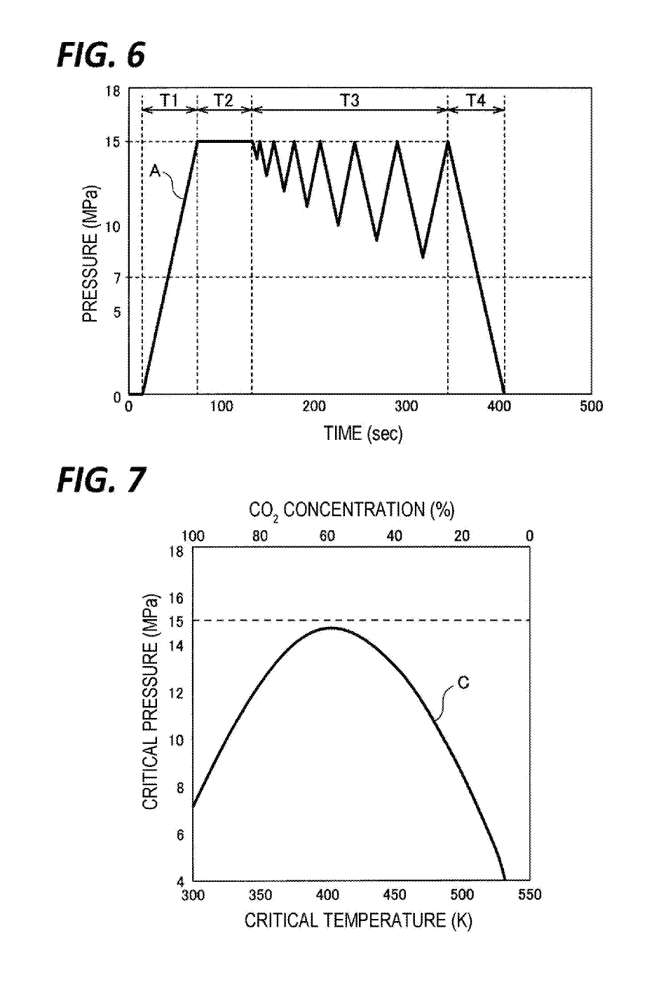

Next, the processing fluid (CO₂) is supplied into the processing container 301 in accordance with the order illustrated in the timing chart of FIG. 6, whereby the drying processing of the wafer W is performed. The fold line A illustrated in FIG. 6 represents a relationship between the elapsed time from the start of the drying processing and the pressure in the processing container 301.

<Pressure-Increasing Step>

First, a pressure-increasing step T1 is performed, and CO₂ (carbon dioxide) as a processing fluid is supplied from the fluid supply tank 51 into the processing container 301. The opening/closing valve 52a is in a closed state immediately before the start of the pressure-increasing step, and a section between the fluid supply tank 51 and the opening/closing valve 52a of the main supply line 50 is filled with CO₂ at a pressure higher than the critical pressure (i.e., the pressure of the processing fluid supplied from the fluid supply tank 51, e.g., 16 MPa to 20 MPa), that is, CO₂ in a supercritical state. In addition, the opening/closing valve 52b is in a closed state, the opening/closing valve 52c is in an opened state, and the pressure in the section on the downstream side of the opening/closing valve 52a on the main supply line 50 and the pressure in the second supply line 64 are set to be the same normal pressure as that in the processing container 301. Further, the opening/closing valves 52f, 52g, 52h, and 52i are opened, and the opening/closing valves 52d, 52e, and 52j are closed. The needle valves 61a and 61b are adjusted to a predetermined opening degree. The set pressure of the back pressure valve 59 is set to a pressure of, for example, 15 MPa, such that CO₂ in the processing container 301 may maintain the supercritical state.

The pressure-increasing step is started by opening the opening/closing valve 52a from the above-described state. When the opening/closing valve 52a is opened, the supercritical CO₂ flows to the downstream side and passes through the orifice 55a. The pressure of CO₂ becomes lower than the critical pressure due to the pressure loss caused by the passing of the orifice 55a, and the CO₂ in the supercritical state is changed to CO₂ in the gaseous state. The CO₂ in the gaseous state passes through the filter 57, and the particles included in the CO₂ gas are captured by the filter 57. The CO₂ gas passing through the filter 57 is discharged from the fluid supply nozzle 341 directly below the center of the wafer W toward the lower surface of the holding plate 316.

The CO₂ discharged from the fluid supply nozzle 341 (see, e.g., arrow “F1” of FIG. 3) collides with the holding plate 316 covering the lower surface of the wafer W and then radially spreads along the lower surface of the holding plate 316 (see, e.g., arrow “F2” of FIG. 3). Thereafter, the discharged CO₂ passes through a gap between the end edge of the holding plate 316 and the sidewall of the container body 311 and the opening 316a of the holding plate 316, and flows into the space on the upper surface side of the wafer W (see, e.g., arrow “F3” of FIG. 3). Since the back pressure valve 59 is maintained fully closed to the set pressure (15 MPa), the CO₂ does not flow out of the processing container 301. Therefore, the pressure in the processing container 301 is gradually increased.

At the initial stage of the pressure-increasing step T1, the pressure of the CO₂ in the supercritical state sent out from the fluid supply tank 51 decreases when passing through the orifice 55a, and also decreases when flowing into the processing container 301 in a normal pressure state. Therefore, at the initial stage of the pressure-increasing step T1, the pressure of the CO₂ flowing into the processing container 301 is lower than the critical pressure (e.g., about 7 MPa), that is, the CO₂ flows into the processing container 301 in the gaseous state. Thereafter, when the pressure in the processing container 301 increases as the processing container 301 is filled with CO₂, and the pressure in the processing container 301 exceeds the critical pressure, the CO₂ present in the processing container 301 becomes a supercritical state.

In the pressure-increasing step T1, when the pressure in the processing container 301 increases to exceed the critical pressure, the processing fluid in the processing container 301 becomes a supercritical state, and the IPA on the wafer W starts to dissolve in the supercritical processing fluid. Then, the mixing ratio of IPA and CO₂ in the mixed fluid consisting of CO₂ and IPA is changed. Meanwhile, the mixing ratio is not considered to be uniform over the entire surface of the wafer W. In order to suppress the pattern collapse caused by an unexpected evaporation of the mixed fluid, in the pressure-increasing step T1, the pressure in the processing container 301 is increased to the pressure to ensure that the CO₂ in the processing container 301 becomes supercritical regardless of the CO₂ concentration in the mixed fluid, that is, 15 MPa. Here, the phrase “the pressure to ensure that the CO₂ in the processing container 301 becomes supercritical” refers to a pressure higher than the maximum value of the pressure indicated by the curve C in the graph of FIG. 7. This pressure (15 MPa) is called a “processing pressure.”

As the pressure in the processing container 301 increases, the pressure in the first and second supply lines 63 and 64 and the main supply line 50 also increases. When the pressure in the main supply line 50 exceeds the critical pressure of CO₂, the CO₂ passing through the filter 57 becomes supercritical.

<Maintaining Step>

When the pressure in the processing container 301 is increased to the above-described processing pressure (15 MPa) by the above pressure-increasing step T1, the opening/closing valve 52b and the opening/closing valve 52f located on the upstream side and the downstream side of the processing container 301, respectively, are closed, and the process proceeds to a maintaining step T2 for maintaining the pressure in the processing container 301. This maintaining step continues until the IPA concentration and the CO₂ concentration in the mixed fluid in the recess of the pattern P of the wafer W become predetermined concentrations (e.g., the IPA concentration is 30% or less and the CO₂ concentration is 70% or more). The time of the maintaining step T2 may be determined by an experiment. In this maintaining step T2, the opened/closed state of the other valve is the same as the opened/closed state in the pressure-increasing step T1.

<Circulating Step>

After the maintaining step T2, a circulating step T3 is performed. The circulating step T3 may be performed by alternately repeating a pressure-lowering step of lowering the pressure in the processing container 301 by discharging the mixed fluid of CO₂ and IPA from the processing container 301, and a pressure-increasing step of increasing the pressure in the processing container 301 by supplying new CO₂ not containing IPA from the fluid supply tank 51 to the processing container 301.

The circulating step T3 is performed, for example, by opening the opening/closing valve 52b and the opening/closing valve 52f, and repeatedly increasing and lowering the set pressure of the back pressure valve 59. Alternatively, the circulating step T3 may be performed by repeating the opening/closing of the opening/closing valve 52f in a state where the opening/closing valve 52b is opened and the set pressure of the back pressure valve 59 is set at a low value.

In the circulating step T3, CO₂ is supplied into the processing container 301 using the fluid supply header 317 (see, e.g., arrow “F4” of FIG. 3). The fluid supply header 317 may supply CO₂ at a higher flow rate than the fluid supply nozzle 341. In the circulating step T3, since the pressure in the processing container 301 is maintained at a pressure sufficiently higher than the critical pressure, even when the CO₂ at a high flow rate collides with the surface of the wafer W or flows near the surface of the wafer W, there is no problem of drying. For this reason, the fluid supply header 317 is used in order to shorten the processing time.

In the pressure-increasing step, the pressure in the processing container 301 is increased to the above-described processing pressure (15 MPa). In the pressure-lowering step, the pressure in the processing container 301 is lowered from the above-described processing pressure to a predetermined pressure (a pressure higher than the critical pressure). In the pressure-lowering step, since the processing fluid is supplied into the processing container 301 via the fluid supply header 317 and the processing fluid is discharged from the processing container 301 through the fluid discharge header 318, a laminar flow of the processing fluid flowing substantially parallel to the surface of the wafer W is formed in the processing container 301 (see, e.g., arrow “F6” of FIG. 3).

By performing the circulating step, the replacement of IPA with CO₂ in the recess of the pattern of the wafer W is facilitated. As the replacement of IPA with CO₂ in the recess progresses, the critical pressure of the mixed fluid decreases as illustrated on the left side of FIG. 7. Therefore, the pressure in the processing container 301 at the end of each of pressure-lowering steps may be gradually lowered while satisfying that the pressure is higher than the critical pressure of the mixed fluid corresponding to the CO₂ concentration in the mixed fluid.

<Discharging Step>

While the replacement of IPA with CO₂ in the recess of the pattern is completed by the circulating step T3, a discharging step T4 is performed. The discharging step T4 may be performed by closing the opening/closing valve 52a, setting the set pressure of the back pressure valve 59 at a normal pressure, opening the opening/closing valves 52b, 52c, 52d, 52e, 52f, 52g, 52h, and 52i), and closing the opening/closing valve 52j. When the pressure in the processing container 301 becomes lower than the critical pressure of the CO₂ by the discharging step T4, the supercritical CO₂ evaporates and is separated from the recess of the pattern. As a result, a drying step for one sheet of wafer W is completed.

Meanwhile, since the opening/closing valve 52a is closed at the end of the discharging step, the section between the fluid supply tank 51 and the opening/closing valve 52a of the main supply line 50 is filled with the supercritical CO₂, as in the time immediately before the start of the pressure-increasing step. Further, the fluid line located on the downstream side of the opening/closing valve 52a of all the fluid lines (pipes) illustrated in FIG. 4 is atmospheric atmosphere at a normal pressure.

According to the above-described exemplary embodiment, the filter 57 may efficiently capture the particles contained in the CO₂ (processing fluid) supplied from the fluid supply tank 51 to the processing container 301. That is, according to the above-described exemplary embodiment, after the start of the pressure-increasing step, CO₂ in the gaseous state passes through the filter 57 until the pressure near the filter 57 of the main supply line 50 exceeds the critical pressure of the CO₂ which is the processing fluid. The filtration performance of the filter 57 is significantly higher when the fluid passing through the filter 57 is in a gaseous state than in a supercritical state. Therefore, in the filling step, since the filtration performance of the filter within a period in which the CO₂ passing through the filter 57 is in the gaseous state may be significantly improved, the amount of the particles supplied into the processing container 301 may be significantly reduced. As a result, the amount of the particles attached to the processed wafer may be significantly reduced.

It is assumed that the opening/closing valve 52a is opened and the opening/closing valves 52b and 52c are closed at the point in time immediately before the start of the pressure-increasing step, the section between the fluid supply tank 51 to the opening/closing valves 52b and 52c is filled with the supercritical CO₂, and the pressure-increasing step is started by opening the opening/closing valve 52c from this state (Comparative Example). In this case, the CO₂ passing through the filter 57 is in a supercritical state immediately after the start of the pressure-increasing step, and the filtration performance of the filter 57 may not be sufficiently exerted.

As a result of actually performing the processing of the wafer W according to the order of the above-described exemplary embodiment, about 680 particles having a size of 30 nm or more attached to the wafer W after the processing were obtained. In the above-described Comparative Example, about 55,300 particles having a size of 30 nm or more attached to the processed wafer W were obtained.

In the above-described exemplary embodiment, one orifice 55a and one filter 57 are arranged in series in the supply line (main supply line 50) connecting the fluid supply tank 51 and the processing container 301, but the present disclosure is not limited thereto.

For example, as illustrated schematically in FIG. 9, a branch line 50A may be formed that branches off from the main supply line 50 on the upstream side of the orifice (first throttle) 55a and joins the main supply line 50 on the downstream side of the orifice 55a again, and an orifice (second throttle) 55aA may be provided in the branch line 50A. Two or more branch lines provided with orifices may be formed. In this way, the flow rate of the fluid passing through the filter 57 may be reduced so that the filtration performance of the filter 57 may be further improved.

Further, as illustrated schematically in FIG. 10, a branch line 50B may be formed in the main supply line 50 that branches off from the main supply line 50 on the upstream side of the orifice (first throttle) 55a and joins the main supply line 50 on the downstream side of the filter (first filter) 57 again, and an orifice (second throttle) 55aB and a filter (second filter) 57B may be provided in the branch line 50B. Even in this way, the flow rate of the fluid passing through the filter 57 may be reduced so that the filtration performance of the filter 57 may be further improved.

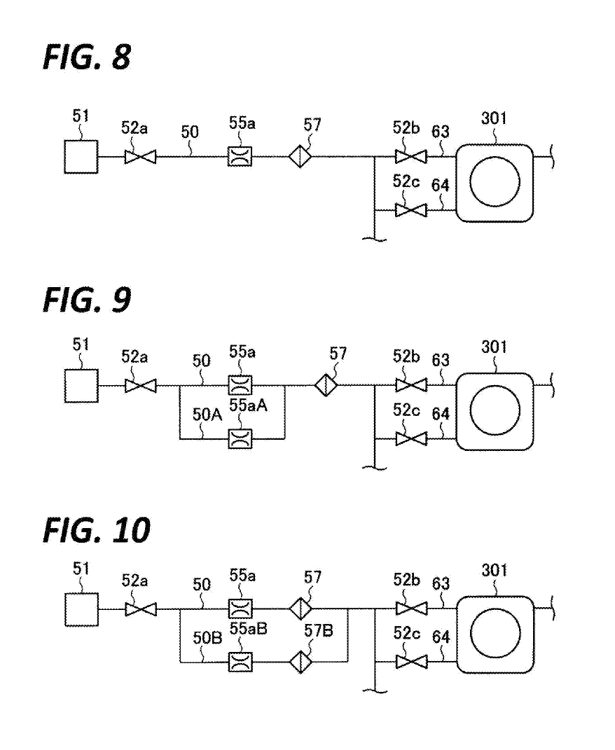

In the meantime, FIG. 8 is a simplified view drawn by omitting the unnecessary elements in the piping system diagram of FIG. 4 for explaining the above operation, and FIGS. 9 and 10 are views drawn based on FIG. 8. Thus, even the configuration examples of FIGS. 9 and 10 may include the elements that are omitted from FIG. 8.

In the above-described exemplary embodiment, orifices 55a, 55aA, and 55aB are used as throttles to reduce the pressure of the CO₂ in the supercritical state flowing through the main supply line 50 and change the state thereof to a gaseous state, but the present disclosure is not limited thereto. (In the present specification, the term “orifice” means a member having pores with unchanged pore diameters through which the fluid passes.) As for the throttle, a variable throttle such as a needle valve may be used instead of a fixed throttle such as an orifice.

In the apparatus in which the supply line (main supply line 50) connecting the fluid supply tank 51 and the processing container 301 does not branch off into two or more supply lines (the first supply line 63 and the second supply line 64) on the way, as in the above-described exemplary embodiment, and the fluid supply tank 51 and the processing container 301 are connected by a single supply line, the opening/closing valve 52b may not be provided between the filter 57 and the processing container 301.

Since the processing fluid is heated by the heater H provided on the upstream side and the downstream side of the orifice 55a as in the above-described exemplary embodiment, the temperature of the processing fluid may be suppressed from being lowered by passing through the orifice 55a. As a result, since the particles contained in the CO₂ that passes through the orifice 55a are in a gaseous state without condensation, the filtration performance of the filter 57 may be sufficiently exerted.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus for processing a substrate using a supercritical processing fluid, the substrate processing apparatus comprising:
a processing container in which the substrate is accommodated;
a supply line configured to connect the processing container with a fluid source that delivers the supercritical processing fluid;
a first opening/closing valve provided in the supply line;
a first throttle provided on a downstream side of the first opening/closing valve of the supply line and configured to change the supercritical processing fluid flowing through the supply line to a gaseous state when a pressure within the processing container is equal to or lower than a critical pressure of the processing fluid; and
a first filter provided on a downstream side of the first throttle of the supply line.

2. The substrate processing apparatus of claim 1, wherein the first throttle includes an orifice having a pore with an unchanged pore diameter, or a variable throttle valve.

3. The substrate processing apparatus of claim 1, further comprising:
a branch line that branches off from the supply line at a position between the first opening/closing valve and the first throttle, and joins the supply line at a position between the first throttle and the first filter,
wherein a second throttle is provided in the branch line.

4. The substrate processing apparatus of claim 1, further comprising:
a branch line that branches off from the supply line at a position between the first opening/closing valve and the first throttle and joins the supply line at a position between the first filter and the processing container,
wherein a second throttle and a second filter are provided in the branch line.

5. A substrate processing apparatus for processing a substrate using a supercritical processing fluid, the substrate processing apparatus comprising:
a processing container in which the substrate is accommodated;
a supply line configured to connect the processing container with a fluid source that delivers the supercritical processing fluid;
a first opening/closing valve provided in the supply line;
a first throttle provided on a downstream side of the first opening/closing valve of the supply line;
a first filter provided on a downstream side of the first throttle of the supply line;
a first branch line that branches off from the supply line at a position between the first opening/closing valve and the first throttle, and joins the supply line at a position between the first throttle and the first filter; and
a second throttle provided in the first branch line.

6. A substrate processing apparatus for processing a substrate using a supercritical processing fluid, the substrate processing apparatus comprising:
a processing container in which the substrate is accommodated;
a supply line configured to connect the processing container with a fluid source that delivers the supercritical processing fluid;
a first opening/closing valve provided in the supply line;
a first throttle provided on a downstream side of the first opening/closing valve of the supply line;
a first filter provided on a downstream side of the first throttle of the supply line;
a first branch line that branches off from the supply line at a position between the first opening/closing valve and the first throttle, and joins the supply line at a position between the first filter and the processing container; and
a second throttle and a second filter provided in the first branch line.

7. A substrate processing method comprising:
carrying the substrate into a processing container in which the substrate is accommodated; and
filling an inside of the processing container accommodating the substrate with a supercritical processing fluid by supplying the processing container with a processing fluid from a fluid source,
wherein, in the filling, when a pressure within the processing container is equal to or lower than a critical pressure of the processing fluid, the supercritical processing fluid supplied from the fluid source is changed to a gaseous state and supplied to the processing container through a first filter.

8. A non-transitory computer-readable storage medium storing a computer executable program that, when executed, causes a computer to control an operation of a substrate processing apparatus and execute the substrate processing method of claim 7.
